(19) United States
(12) Patent Application Publication
(10) Pub. No.: US 2022/0131013 A1
(43) Pub. Date: Apr. 28, 2022

(54) MULTI-CHANNEL GATE-ALL-AROUND HIGH-ELECTRON-MOBILITY TRANSISTOR

(71) Applicant: QUALCOMM Incorporated, San Diego, CA (US)

(72) Inventors: Chenjie TANG, San Diego, CA (US); Gengming TAO, San Diego, CA (US); Ye LU, San Diego, CA (US); Bin YANG, San Diego, CA (US); Xia LI, San Diego, CA (US)

(21) Appl. No.: 17/077,807

(22) Filed: Oct. 22, 2020

(51) Int. Cl. H01L 29/786; H01L 29/06; H01L 29/205; H01L 29/423; H01L 21/02; H01L 29/66

(52) U.S. Cl. CPC H01L 29/78696; H01L 29/0673; H01L 29/205; H01L 29/42392; H01L 29/78618; H01L 29/66742; H01L 21/02603; H01L 21/02543; H01L 21/02546; H01L 29/66522; H01L 29/78681

(57) ABSTRACT

Certain aspects of the present disclosure generally relate to a semiconductor device implemented with multiple channels in a gate-all-around (GAA) high-electron-mobility transistor (HEMT) and techniques for fabricating such a device. One example semiconductor device generally includes a substrate; a first gate layer disposed above the substrate; a first barrier layer disposed above the first gate layer; a first channel region disposed above the first barrier layer; a second barrier layer disposed above the first channel region; a second gate layer disposed above the second barrier layer; a third barrier layer disposed above the second gate layer; a second channel region disposed above the third barrier layer; a fourth barrier layer disposed above the second channel region; a source region; and a drain region.

### BACKGROUND

### Field of the Disclosure

Certain aspects of the present disclosure generally relate to electronic components and, more particularly, to a semiconductor device.

### Description of Related Art

A continued emphasis in semiconductor technology is to create improved performance semiconductor devices at competitive prices and with smaller sizes. This emphasis over the years has resulted in extreme miniaturization of semiconductor devices, made possible by continued advances in semiconductor processes and materials in combination with new and sophisticated device designs. Large numbers of transistors are employed in integrated circuits (ICs) in many electronic devices. For example, components such as central processing units (CPUs), graphics processing units (GPUs), and memory systems each employ a large quantity of transistors for logic circuits and memory devices.

Gate-all-around (GAA) field-effect transistors (FETs) have enabled a reduction of transistor node sizes. GAA FETs have nanowires (or nanosheets) forming the channels, which are embedded in gate material disposed between the source and drain of the GAA FET. GAA FETs may be designed to have a lower threshold voltage than similarly sized fin field-effect transistor (FinFET) devices because GAA FETs may have better short-channel control, allowing for a reduction in supply voltage that lowers power consumption in electronic systems.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description” one will understand how the features of this disclosure provide advantages that include improved channel control, reduced current leakage, and increased on-state current.

Certain aspects of the present disclosure are directed to a transistor. This transistor generally includes a substrate; a first gate layer disposed above the substrate; a first barrier layer disposed above the first gate layer; a first channel region disposed above the first barrier layer; a second barrier layer disposed above the first channel region; a second gate layer disposed above the second barrier layer; a third barrier layer disposed above the second gate layer; a second channel region disposed above the third barrier layer; a fourth barrier layer disposed above the second channel region; a source region; and a drain region.

Other aspects of the present disclosure relate to a method for fabricating a semiconductor device. This method generally includes forming a first barrier layer above a substrate; forming a first channel region above the first barrier layer; forming a second barrier layer above the first channel region; forming a first gate layer above the substrate, wherein the first barrier layer is disposed above the first gate layer; forming a second gate layer above the second barrier layer; forming a third barrier layer above the second barrier layer; forming a second channel region above the third barrier layer; forming a fourth barrier layer above the second channel region; forming a source region; and forming a drain region.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIGS. 1A-1C illustrate cross-sectional views of an example semiconductor device, in accordance with certain aspects of the present disclosure.

FIGS. 2A-2C illustrate cross-sectional views of an example semiconductor device having a source and a drain, each implemented with a doped semiconductor region adjacent to channel regions, in accordance with certain aspects of the present disclosure.

FIGS. 3A-3C illustrate cross-sectional views of an example semiconductor device having a source and a drain implemented adjacent to multiple sides of channel regions, in accordance with certain aspects of the present disclosure.

FIG. 4 illustrates a cross-sectional view of an example semiconductor device with a source and a drain, each implemented with a doped semiconductor region above channel regions, in accordance with certain aspects of the present disclosure.

FIGS. 5A-5I illustrate cross-sectional views of example fabrication processes for a semiconductor device, in accordance with certain aspects of the present disclosure.

FIG. 6 is a flow diagram of example operations for fabricating a semiconductor device, in accordance with certain aspects of the present disclosure.

FIGS. 7A-7F illustrate cross-sectional views of example fabrication processes for a semiconductor device having a gate dielectric, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure relate to a gate-all-around (GAA) high-electron-mobility transistor (HEMT) having multiple channel regions disposed adjacent to or below a source region and a drain region. Certain aspects provide increased current density and power performance as well as improved gate control in a multi-channel semiconductor device as compared to conventional implementations.

For fifth-generation (5G) power amplifier (PA) devices, higher power density is desired. To increase power density, current density or breakdown voltage of the device may be increased. Conventionally, HEMTs may be implemented with a single gate controlling a single channel. In this case, however, a short-channel effect may occur, leading to a relatively low current density, as well as a relatively low transconductance. To mitigate these effects, such transistors may be implemented as GAA transistors. GAA transistors may provide for improved channel control, reduced current leakage, and increased on-state current.

Certain aspects of the present disclosure provide techniques for further improving current density of a GAA semiconductor device implemented as a HEMT by employing multiple channels (e.g., three or more channels). The GAA semiconductor device described herein provides increased transconductance, improved gate control, and further reductions in short-channel effects provided by GAA technology. Certain aspects further provide recessed source or drain (S/D) contacts, regrown n+ doped S/D regions, or S/D regions implemented using a metal adjacent to multiple sides of channels, for improved electrical coupling to channels of the semiconductor device, as described in more detail herein.

### Example Semiconductor Devices

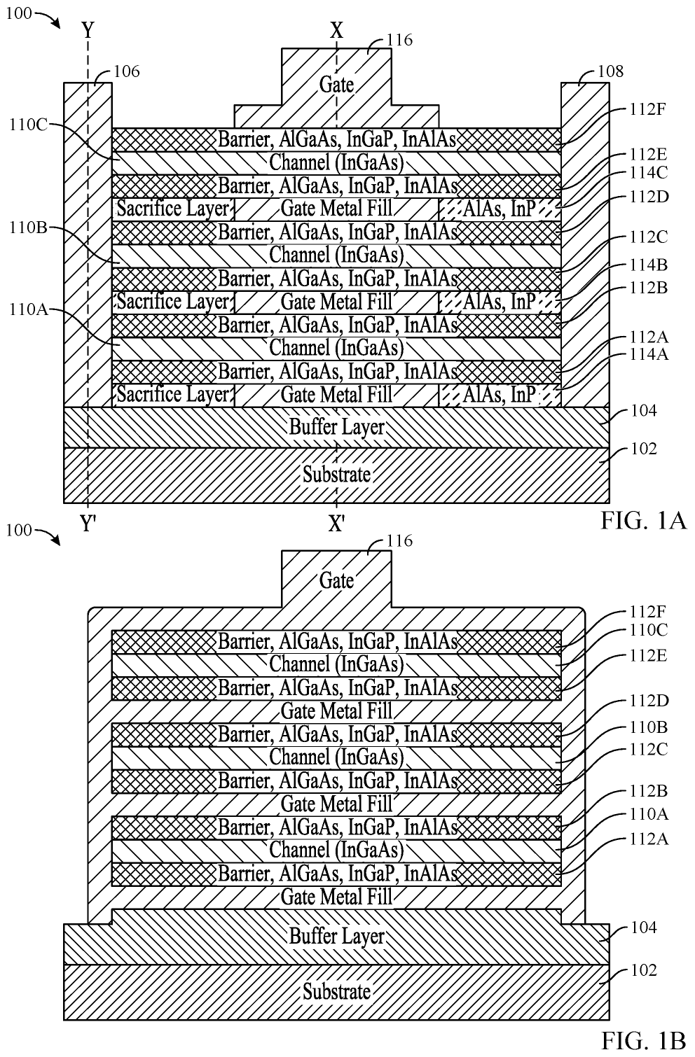

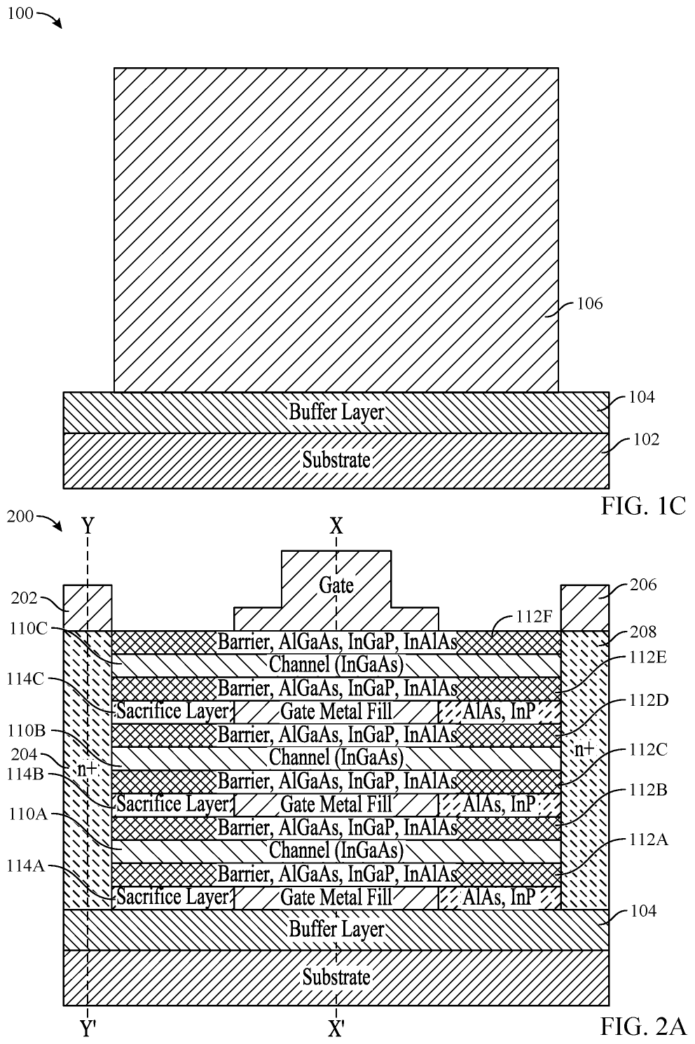

FIGS. 1A-1C illustrate cross-sectional views of an example semiconductor device 100 with a source region and a drain region implemented with metal adjacent to channel regions, in accordance with certain aspects of the present disclosure. The semiconductor device 100 may be a GAA HEMT, which may include S/D terminals 106, 108 (also referred to as “S/D contacts”); a gate region 116; channel regions 110A, 110B, 110C (collectively referred to as “channel regions 110”); barrier layers 112A, 112B, 112C, 112D, 112E, 112F (collectively referred to as “barrier layers 112”); and sacrificial layers 114A, 114B, 114C (collectively referred to as “sacrificial layers 114”), all disposed above a buffer layer 104 and a substrate 102. For example, the S/D terminal 106 may be considered part of or coupled to a source region, and the S/D terminal 108 may be considered part of or coupled to a drain region. Alternatively, the S/D terminal 106 may be part of or coupled to a drain region, and the S/D terminal 108 may be part of or coupled to a source region. Although only three channel regions 110 are depicted, it should be appreciated that the techniques described herein may be implemented with more than three channel regions.

The substrate 102 may be composed of gallium arsenide (GaAs), silicon (Si), indium phosphide (InP), or any other suitable material, such as any suitable Group III-V semiconductor material. As shown, the buffer layer 104 may be disposed above the substrate 102. The buffer layer 104 may be composed of aluminum gallium arsenide (AlGaAs), gallium arsenide (GaAs), or any other suitable material. The buffer layer 104 may provide for transitioning between the substrate 102 and the semiconductor layers (e.g., the channel regions 110) of the semiconductor device 100, for example, to provide for growth without cracking. As shown, the S/D terminal 106 and the S/D terminal 108 may be disposed above the buffer layer 104. The S/D terminal 106 and the S/D terminal 108 may each be composed of a metal or metal stack, such as copper, titanium, aluminum or any other suitable material. In some cases, the S/D terminals 106, 108 may be coupled to semiconductor regions (e.g., alternating layers of different semiconductor materials) forming respective S/D semiconductor regions. In certain aspects, the semiconductor device 100 may include multiple channel regions 110 disposed between the S/D terminal 106 and the S/D terminal 108. Although three channel regions 110 are shown, the semiconductor device may include two channel regions (e.g., channel regions 110A, 110B), or, alternatively, more than three channel regions 110. In certain aspects, the channel regions 110 are composed of Group III-V materials, such as indium gallium arsenide (InGaAs), or any other suitable material.

Each of the channel regions 110 may extend from the S/D region associated with the S/D terminal 106 to the other S/D region associated with the S/D terminal 108. In other words, each of the channel regions 110 may be activated and provide an electrical connection between the S/D terminal 106 and the S/D terminal 108 when the semiconductor device 100 is in an “on” state. Including multiple channel regions 110 may allow for increased current through the semiconductor device 100. As shown, each of the channel regions may be disposed between two of the barrier layers 112. For example, channel region 110A may be disposed between barrier layer 112A and barrier layer 112B, where barrier layer 112A is located above channel region 110A and barrier layer 112B is located below channel region 110A. In certain aspects, the barrier layers 112, similar to the channel regions 110, may extend from the S/D region associated with the S/D terminal 106 to the S/D region associated with the S/D terminal 108. The barrier layers 112 may be composed of AlGaAs, indium gallium phosphide (InGaP), indium aluminum arsenide (InAlAs), or any other suitable material that is at least partially- or delta-doped by impurities to form two-dimensional electron gas in the channel regions 110. The material of the barrier layers 112 may have a bandgap larger than a bandgap of the channel regions 110.

Furthermore, as shown, the gate region 116 is implemented in a gate-all-around fashion, meaning that the gate region 116 surrounds the lateral surface(s) of each of the channel regions 110. As shown in FIG. 1B, which is a cross-sectional view of the semiconductor device 100 along the line X-X′, portions of the gate region 116 may be disposed between two of the barrier layers 112. For example, a portion of the gate region 116 may be disposed between the barrier layer 112B and the barrier layer 112C. Moreover, a portion of the gate region 116 may be disposed above the buffer layer 104 and below the barrier layer 112A, as shown.

As shown in FIG. 1A, the semiconductor device 100 may include sacrificial layers 114 disposed laterally adjacent to portions of the gate region 116. For example, during fabrication of the semiconductor device 100, sacrificial layers may be formed, followed by removal of a portion of each of the sacrificial layers to facilitate formation of the gate region 116 (e.g., labeled “gate metal fill” in FIG. 1A), as will be described in more detail herein. The sacrificial layers 114 may be composed of aluminum arsenide (AlAs), indium phosphide (InP), or any other suitable material. The gate metal fill may also be referred to herein as a “gate layer.” For example, a portion of the gate region 116 disposed between the barrier layer 112D and the barrier layer 112E may be considered a gate layer.

As shown in FIG. 1B, the gate region 116 may be formed to be adjacent to at least one side of each of the barrier layers 112 and each of the channel regions 110. For example, the gate region 116 may surround the barrier layer 112E, the channel region 110C, and the barrier layer 112F, as shown. Furthermore, a portion of the buffer layer 104 may be disposed between portions of the gate region 116, as illustrated.

FIG. 1C is a cross-sectional view of the semiconductor device 100 along the line Y-Y′ of FIG. 1A. As shown, the S/D terminal 106 extends above a portion of the buffer layer 104. A similar cross section may be taken through the S/D terminal 108, which may also extend above a portion of the buffer layer 104 in a similar manner to the S/D terminal 106.

Implementing multiple channel regions in a GAA HEMT, such as the semiconductor device 100 with multiple channel regions 110, provides improved current density and improved electrical coupling for channels of the GAA HEMT.

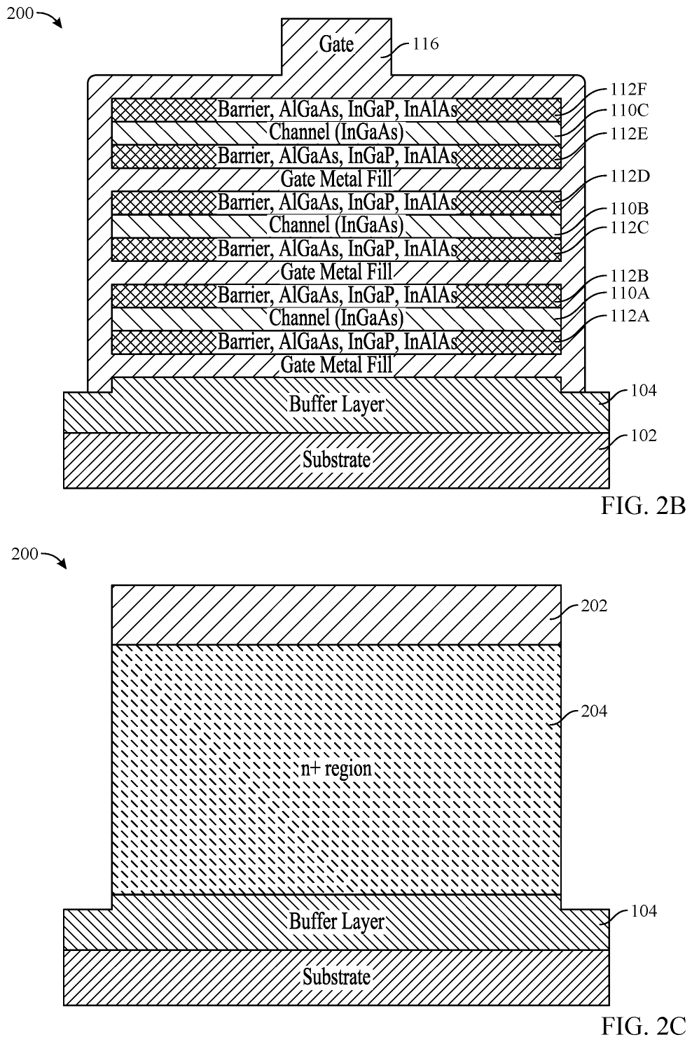

FIGS. 2A-2C illustrate cross-sectional views of an example semiconductor device 200 having a source and a drain, each implemented with a doped semiconductor region adjacent to channel regions, in accordance with certain aspects of the present disclosure. FIG. 2B is a cross-sectional view of the semiconductor device 200 along the line X-X′ in FIG. 2A.

As shown in FIG. 2A, the semiconductor device 200 may be similar in construction to the semiconductor device 100 of FIG. 1A. However, the semiconductor device 200 may include doped semiconductor regions 204, 208 disposed above the buffer layer 104 and adjacent to the channel regions 110, the barrier layers 112, and the sacrificial layers 114. Additionally, the semiconductor device 200 may include S/D contacts 202, 206 disposed above the doped semiconductor regions 204, 208, respectively.

As shown, each of the channel regions 110 may extend from the doped semiconductor region 204 to the doped semiconductor region 208. Furthermore, as illustrated, the barrier layers 112, similar to the channel regions 110, may extend between the doped semiconductor region 204 and the doped semiconductor region 208. In certain aspects, during fabrication, the channel regions 110, the barrier layers 112, and the sacrificial layers 114 may be formed first, and may be partially etched (e.g., wet etched) to facilitate formation (e.g., growth) of the doped semiconductor regions 204, 208.

FIG. 2C is a cross-sectional view of the semiconductor device 200 along the line Y-Y′ of FIG. 2A. As shown, doped semiconductor region 204 may extend above a portion of the buffer layer 104, and the S/D contact 202 may extend along at least a portion (e.g., the entire width) of the doped semiconductor region 204. A similar cross section may be taken through the doped semiconductor region 208, which may also extend above a portion of the buffer layer 104 in a similar manner to the doped semiconductor region 204. Furthermore, the S/D contact 206 may extend along at least a portion (e.g., the entire width) of the doped semiconductor region 208.

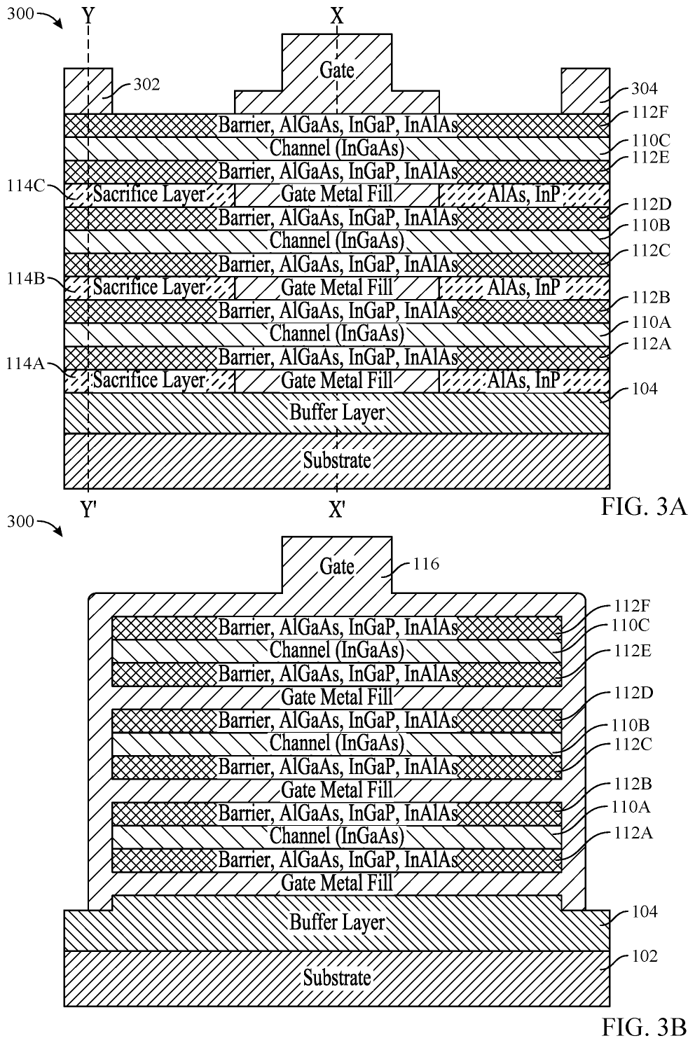

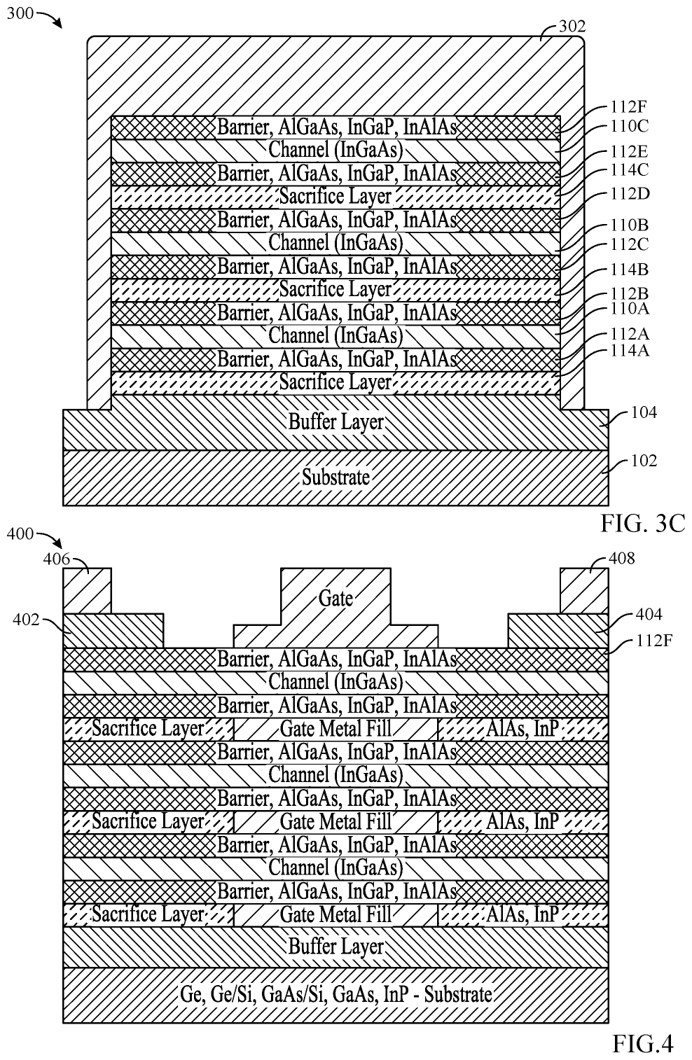

FIGS. 3A-3C illustrate cross-sectional views of an example semiconductor device 300 having a source terminal and a drain terminal implemented adjacent to multiple sides of channel regions, in accordance with certain aspects of the present disclosure. FIG. 3B, is a cross-sectional view of the semiconductor device 300 along the line X-X′ of FIG. 3A.

As shown in FIG. 3A, the semiconductor device 300 may be similar in construction to the semiconductor device 100 of FIG. 1A. However, as illustrated, each of the channel regions 110 and each of the barrier layers 112 may extend from below the S/D terminal 302 to below the S/D terminal 304. Furthermore, as illustrated in FIG. 3C, which is a cross-sectional view of the semiconductor device 300 along the line Y-Y′ of FIG. 3A, S/D terminal 302 may be formed such that the channel regions 110, barrier layers 112, and the sacrificial layers 114 are disposed between portions of the S/D terminal 302. That is, multiple sides of each of the channel regions 110, barrier layers 112, and the sacrificial layers 114 may be adjacent to the S/D terminal 302. Further, the S/D terminal 302 may cover lateral and top surfaces of an end (e.g., the barrier layer 112F) of a stack comprising the channel regions 110, the barrier layers 112, and the sacrificial layers 114. Furthermore, S/D terminal 304 may be formed in a similar manner to the S/D terminal 302.

FIG. 4 illustrates a cross-sectional view of an example semiconductor device 400 with a source and a drain, each implemented with a doped semiconductor region (also referred to as a “cap layer”) above the channel regions, in accordance with certain aspects of the present disclosure.

As shown in FIG. 4, the semiconductor device 400 may be similar in construction to the semiconductor device 300 of FIG. 3A. However, the semiconductor device 400 may include cap layers 402, 404 each disposed above a portion of the uppermost barrier layer (in this case, barrier layer 112F). In certain aspects, the cap layers 402, 404 may be doped semiconductor regions composed of, for example, p-type material or n-type material. Furthermore, as illustrated, the semiconductor device 400 may include S/D contacts 406, 408 disposed above the cap layers 402, 404 respectively. In certain aspects, the S/D contacts 406, 408 may be composed of copper or any other suitable material.

### Example Operations for Fabricating a Semiconductor Device

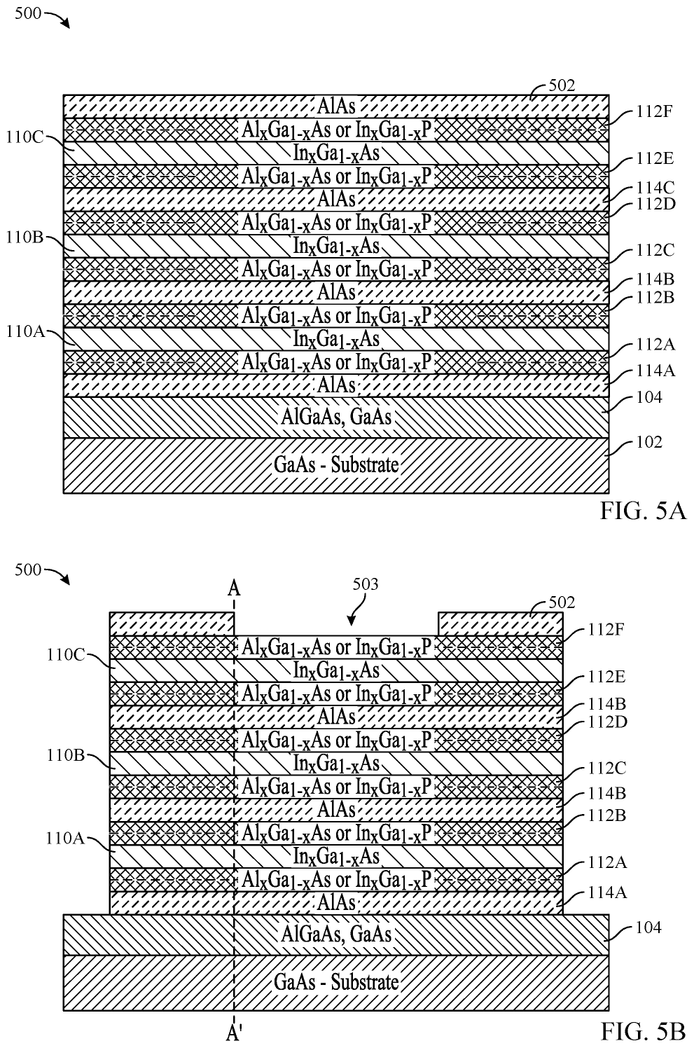

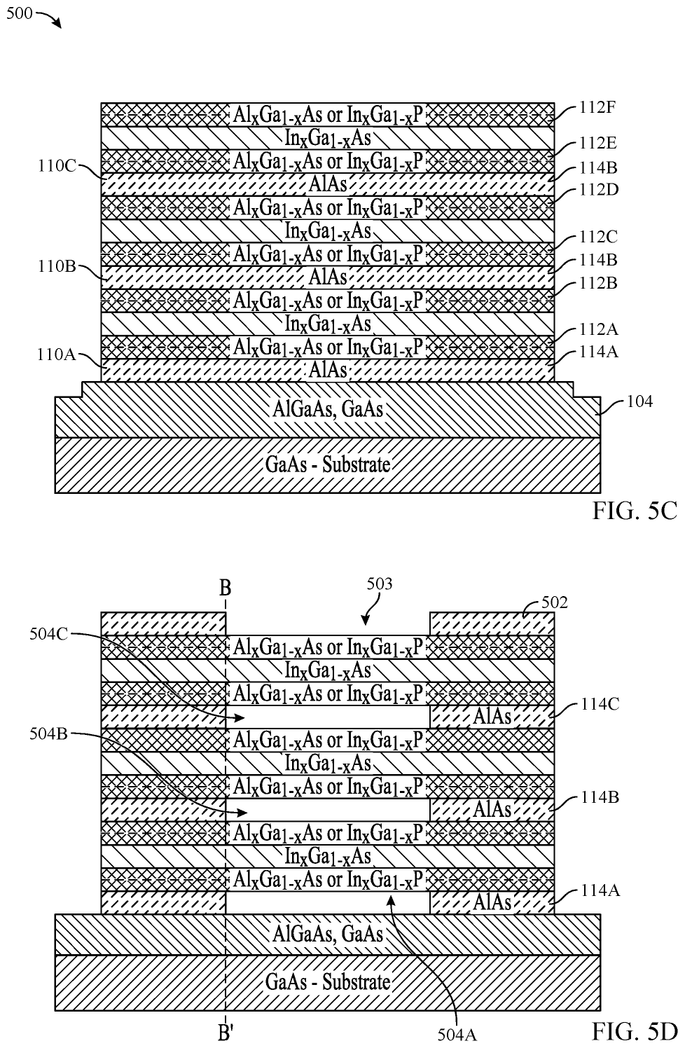

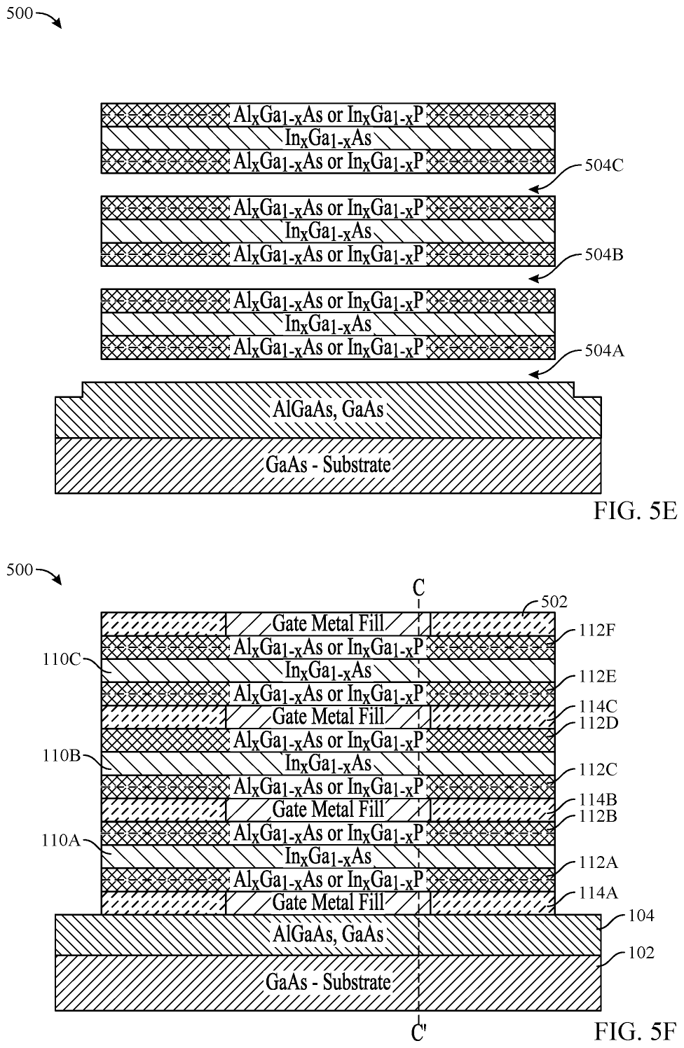

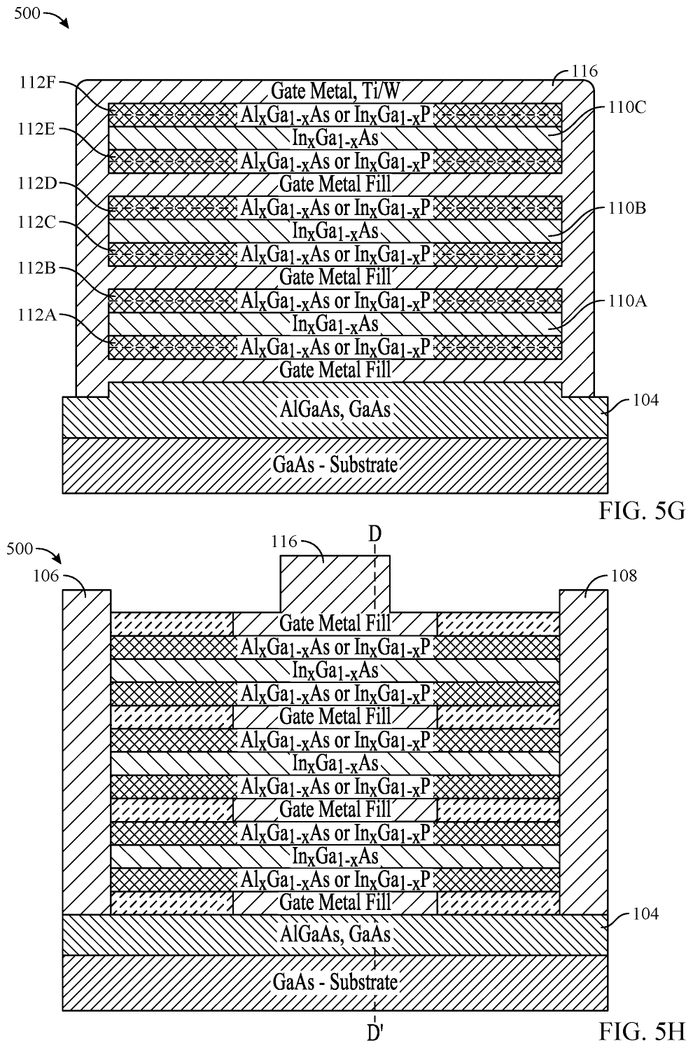

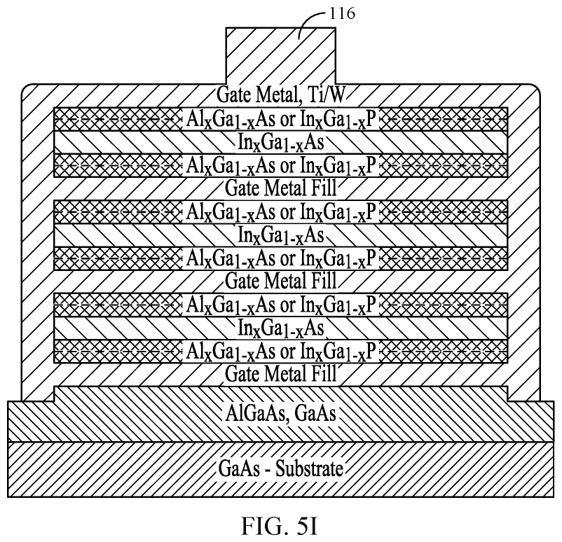

FIGS. 5A-5E illustrate example operations for fabricating a semiconductor device 500 (e.g., the semiconductor device 100 depicted in FIG. 1A), in accordance with certain aspects of the present disclosure.

As shown in FIG. 5A, the substrate 102 and the buffer layer 104 may be formed. Additionally, the channel regions 110, the barrier layers 112, and the sacrificial layers 114 may be formed. Furthermore, a sacrificial layer 502 may be formed above the uppermost barrier layer (e.g., barrier layer 112F). In certain aspects, the channel regions 110 may be n-type delta doped (e.g., the dopant may be highly concentrated in a thin layer). In certain aspects, the barrier layers 112 may be composed of AlₓGa₁₋ₓAs, where x is less than 0.35, for example. Alternatively, the barrier layers 112 may be composed of InₓGa₁₋ₓP, where x is about 0.48, for example.

As shown in FIG. 5B, ends of the channel regions 110, the barrier layers 112, and the sacrificial layers 114 may be processed (e.g., etched) to remove these ends such that the channel regions 110, the barrier layers 112, and the sacrificial layers 114 each extend along a portion of the buffer layer 104. Additionally, a middle portion 503 of the sacrificial layer 502 may be etched or otherwise removed. As shown in FIG. 5C, which is a cross-section of the semiconductor device 500 through the line A-A′ of FIG. 5B, the buffer layer 104 may be etched such that a top portion of the buffer layer 104 has a stepped shape.

As shown in FIG. 5D, a middle portion of each of the sacrificial layers 114 may be etched (e.g., wet etched) or otherwise selectively removed to form gaps 504A, 504B, 504C (collectively referred to as “gaps 504”). This can also be seen in FIG. 5E, which is a cross-section of the semiconductor device 500 through the line B-B′ of FIG. 5D.

As shown in FIG. 5F, the middle portion 503 of the sacrificial layer 502 and gaps 504 may be filled with gate metal for the gate region 116. Furthermore, as illustrated in FIG. 5G, which is a cross-section of the semiconductor device 500 through the line C-C′ of FIG. 5F, the gate region 116 may be formed in a GAA fashion.

As shown in FIG. 511, the S/D terminals 106, 108 may be formed above the buffer layer 104, and an upper portion of the gate region 116 may be formed. This latter aspect can further be seen in FIG. 5I, which is a cross-section view of the semiconductor device 500 through the line D-D′ of FIG. 5F.

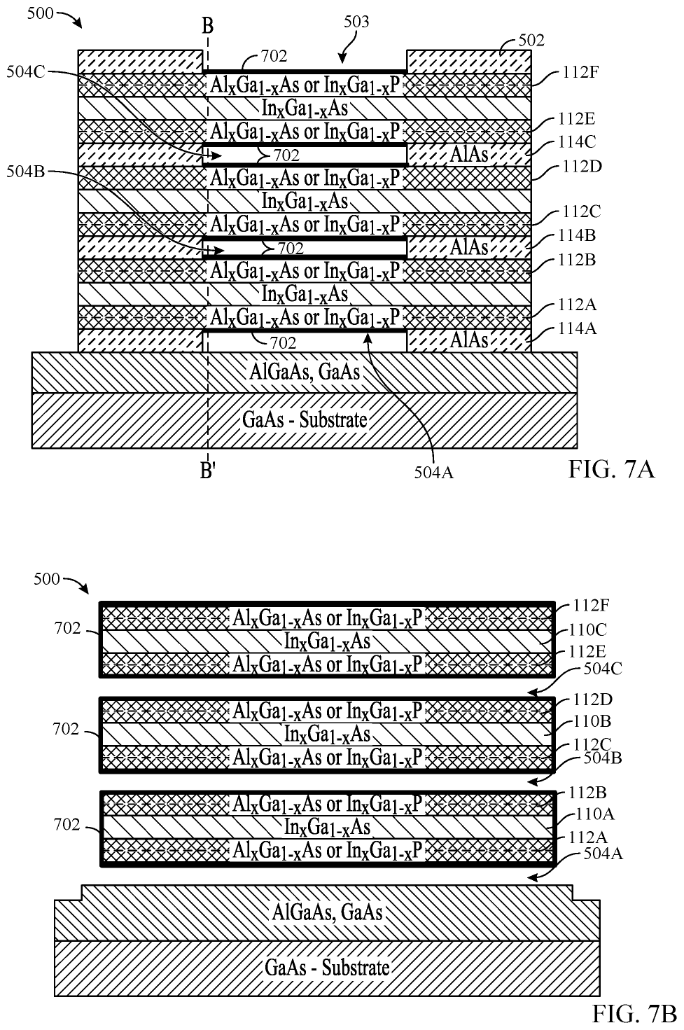

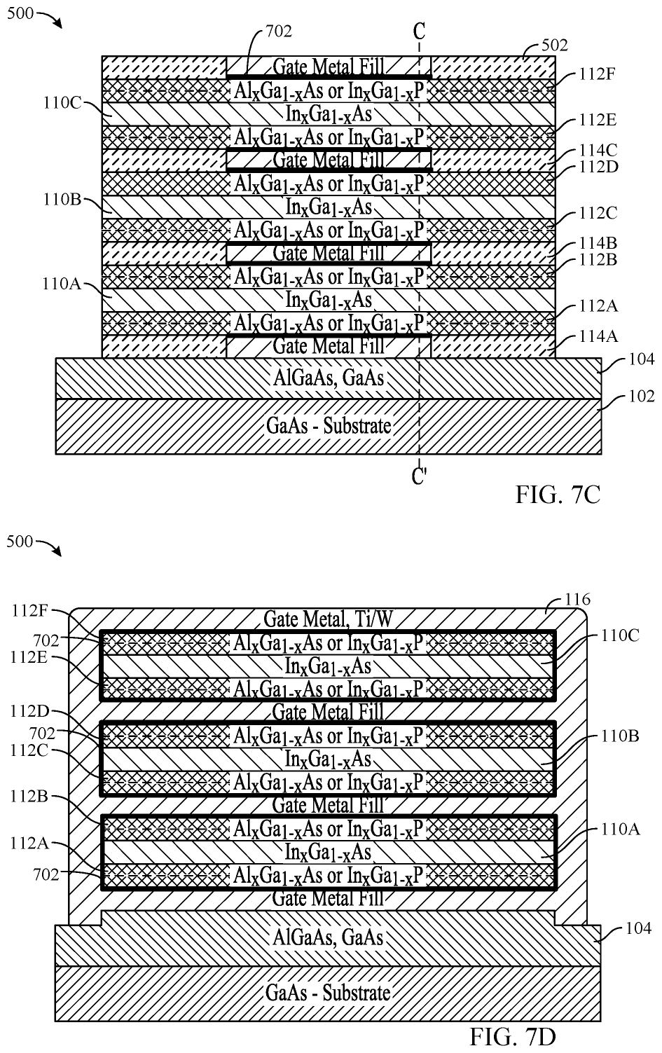

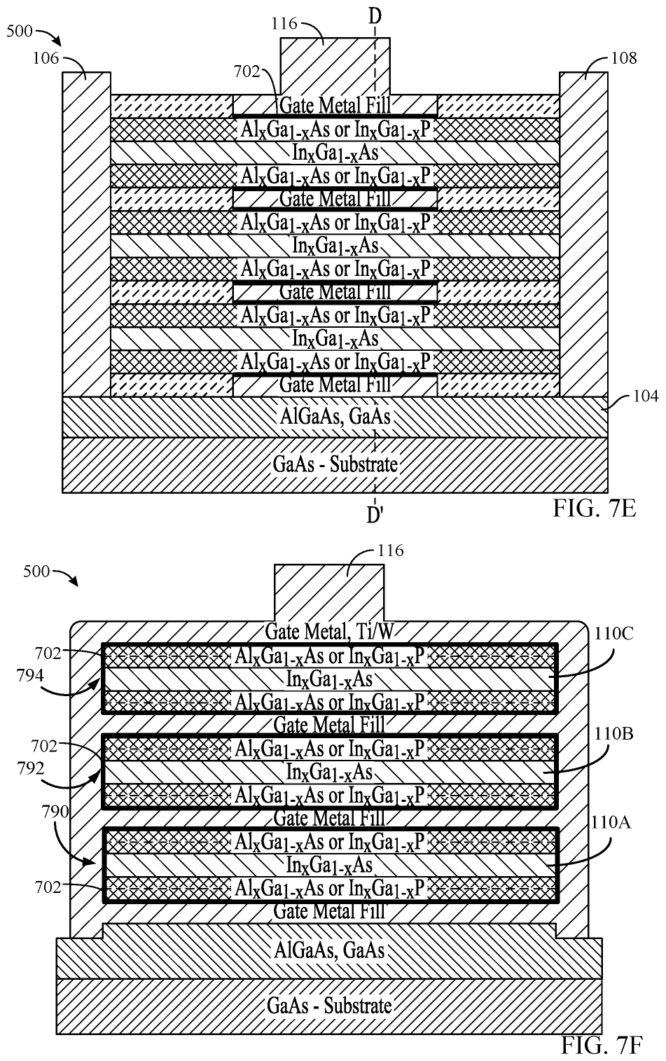

FIGS. 7A-7F illustrate cross-sectional views of example fabrication processes for the semiconductor device 500 implemented with a gate dielectric, in accordance with certain aspects of the present disclosure. Continuing from the etching of the middle portion of each of the sacrificial layers 114 in FIGS. 5D and 5E, a dielectric layer 702 (e.g., also referred to as a “gate dielectric”) may be formed adjacent to a top or bottom portion of each of the barrier layers 112, as well as adjacent to each of the channel regions 110, as shown in FIGS. 7A and 7B. FIG. 7B is a cross-section of the semiconductor device 500 through the line B-B′ of FIG. 7A.

As shown in FIG. 7C, the middle portion 503 of the sacrificial layer 502 and gaps 504 may be filled with gate metal for the gate region 116. Furthermore, as illustrated in FIG. 7D, which is a cross-section of the semiconductor device 500 through the line C-C′ of FIG. 7C, the gate region 116 may be formed in a GAA fashion.

As shown in FIG. 7E, the S/D terminals 106, 108 may be formed above the buffer layer 104, and an upper portion of the gate region 116 may be formed. This latter aspect can further be seen in FIG. 7F, which is a cross-section view of the semiconductor device 500 through the line D-D′ of FIG. 7E.

As shown in FIGS. 7C and 7D, once the gaps 504 are filled with the gate metal for the gate region 116, the dielectric layers 702 may provide electrical isolation between the channel regions 110 and the gate region 116. For example, dielectric layers 702 are formed adjacent to sides 790, 792, 794 of channel regions 110A, 110B, 110C providing electric isolation between the channel regions 110 and the gate region 116. This can also be seen in FIGS. 7E and 7F.

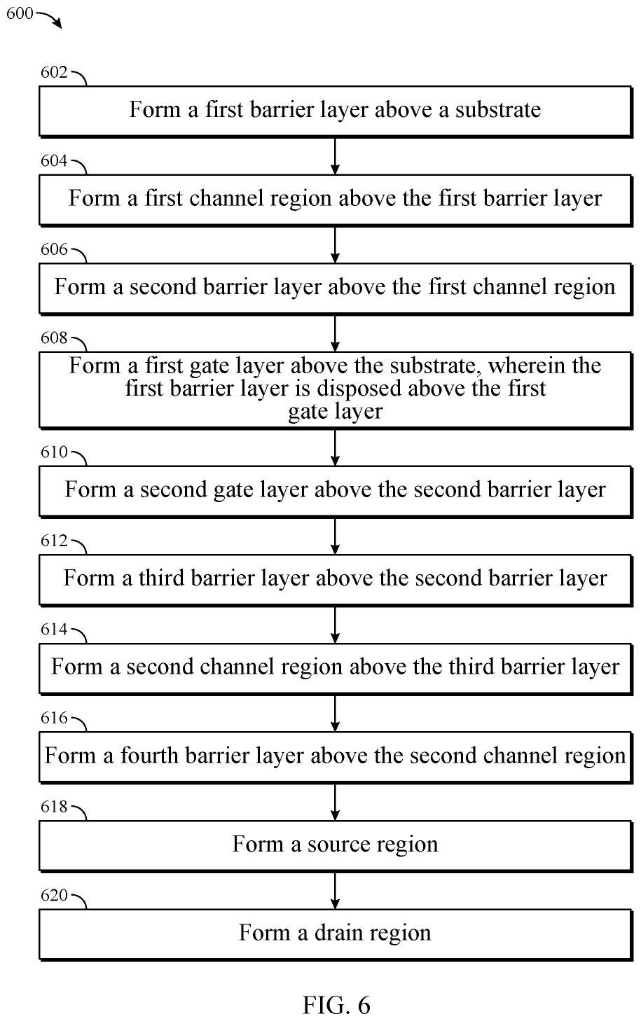

FIG. 6 is a flow diagram of operations 600 for fabricating an exemplary semiconductor device (e.g. the semiconductor device 100 depicted in FIG. 1A), in accordance with certain aspects of the present disclosure. The operations may be performed by a semiconductor fabrication facility, for example.

The operations 600 begin, at block 602, with the facility forming a first barrier layer (e.g., the barrier layer 112A) above a substrate (e.g., the substrate 102). At block 604, the facility forms a first channel region (e.g., the channel region 110A) above the first barrier layer. At block 606, the facility forms a second barrier layer (e.g., the barrier layer 112B) above the first channel region. At block 608, the facility forms a first gate layer (e.g., the metal fill of the gate region 116 between the buffer layer 104 and the barrier layer 112A) above the substrate, the first barrier layer being disposed above the first gate layer. At block 610, the facility forms a second gate layer (e.g., the metal fill of the gate region 116 above the barrier layer 112B) above the second barrier layer. At block 612, the facility forms a third barrier layer (e.g., the barrier layer 112C) above the second gate layer. At block 614, the facility forms a second channel region (e.g., the channel region 110B) above the third barrier layer. At block 616, the facility forms a fourth barrier layer (e.g., the barrier layer 112D) above the second channel region. At block 618, the facility forms a source region (e.g., the S/D terminal 106). At block 620, the facility forms a drain region (e.g., the S/D terminal 108). In some cases, the semiconductor device is a high-electron-mobility transistor (HEMT).

In certain aspects, the facility forms a buffer layer (e.g., the buffer layer 104) above the substrate. In this case, a portion of the buffer layer is below the source region, and another portion of the buffer layer is below the drain region.

In certain aspects, the facility forms a third gate layer (e.g., the gate region 116) above the fourth barrier layer. Further, in this case, the first barrier layer and the second barrier layer extend between a region adjacent to or below the drain region and a region adjacent to or below the source region, and the third barrier layer and the fourth barrier layer extend between the region adjacent to or below the drain region and the region adjacent to or below the source region.

In certain aspects, a portion of the source region is adjacent to a portion of each of the first barrier layer, the second barrier layer, and the first channel region.

In certain aspects, the facility forms the source region by forming a doped semiconductor region and forming a source contact above the doped semiconductor region, the doped semiconductor region having a portion adjacent to a portion of each of the first barrier layer, the second barrier layer, and the first channel region. Further, in some cases, the facility forms the drain region by forming another doped semiconductor region, and forming a drain contact disposed above the other doped semiconductor region, the other doped semiconductor region having a portion adjacent to another portion of each of the first barrier layer, the second barrier layer, and the first channel region.

In certain aspects, the facility forms another doped semiconductor region, where the drain region comprises a drain contact disposed above the other doped semiconductor region. In this case, the other doped semiconductor region has a portion adjacent to another portion of each of the first barrier layer, the second barrier layer, and the first channel region. In certain aspects, each of the first barrier layer, the second barrier layer, and the first channel region is formed between a first portion of the source region and a second portion of the source region (e.g., as illustrated in FIG. 3C).

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A transistor comprising:
a substrate;
a first gate layer disposed above the substrate;
a first barrier layer disposed above the first gate layer;
a first channel region disposed above the first barrier layer;
a second barrier layer disposed above the first channel region;
a second gate layer disposed above the second barrier layer;
a third barrier layer disposed above the second gate layer;
a second channel region disposed above the third barrier layer;
a fourth barrier layer disposed above the second channel region;
a source region; and
a drain region.

2. The transistor of claim 1, wherein the transistor is a high-electron-mobility transistor (HEMT).

3. The transistor of claim 1, further comprising a buffer layer disposed above the substrate, wherein a portion of the buffer layer is below the source region, and wherein another portion of the buffer layer is below the drain region.

4. The transistor of claim 1, further comprising a third gate layer disposed above the fourth barrier layer, and wherein:
the first barrier layer and the second barrier layer extends between a region adjacent to or below the drain region and a region adjacent to or below the source region; and
the third barrier layer and the fourth barrier layer extend between the region adjacent to or below the drain region and the region adjacent to or below the source region.

5. The transistor of claim 1, wherein:
a portion of the source region is adjacent to a portion of each of the first barrier layer, the second barrier layer, and the first channel region; and
a portion of the drain region is adjacent to another portion of each of the first barrier layer, the second barrier layer, and the first channel region.

6. The transistor of claim 1, further comprising a doped semiconductor region, wherein the source region comprises a source contact disposed above the doped semiconductor region, the doped semiconductor region having a portion adjacent to a portion of each of the first barrier layer, the second barrier layer, and the first channel region.

7. The transistor of claim 6, further comprising another doped semiconductor region, wherein the drain region comprises a drain contact disposed above the other doped semiconductor region, the other doped semiconductor region having a portion adjacent to another portion of each of the first barrier layer, the second barrier layer, and the first channel region.

8. The transistor of claim 1, wherein each of the first barrier layer, the second barrier layer, and the first channel region is disposed between a first portion of the source region and a second portion of the source region.

9. The transistor of claim 1, wherein each of the first barrier layer, the second barrier layer, and the first channel region is disposed between a first portion of the drain region and a second portion of the drain region.

10. The transistor of claim 1, further comprising a doped semiconductor region, wherein the source region comprises a source contact disposed above the doped semiconductor region, and wherein each of the first barrier layer, the second barrier layer, and the first channel region have a portion disposed below the doped semiconductor region.

11. The transistor of claim 1, further comprising a doped semiconductor region, wherein the drain region comprises a drain contact disposed above the doped semiconductor region, and wherein each of the first barrier layer, the second barrier layer, and the first channel region have a portion disposed below the doped semiconductor region.

12. The transistor of claim 1, wherein the first channel region comprises indium gallium arsenide (InGaAs).

13. The transistor of claim 1, wherein the first barrier layer and the second barrier layer comprise aluminum gallium arsenide (AlGaAs), indium gallium phosphide (InGaP), or indium aluminum arsenide (InAlAs).

14. The transistor of claim 1, further comprising a dielectric layer disposed adjacent to a lateral side of the first channel region.

15. A method for fabricating a semiconductor device, comprising:
forming a first barrier layer above a substrate;
forming a first channel region above the first barrier layer;
forming a second barrier layer above the first channel region;
forming a first gate layer above the substrate, wherein the first barrier layer is disposed above the first gate layer;
forming a second gate layer above the second barrier layer;
forming a third barrier layer above the second barrier layer;
forming a second channel region above the third barrier layer;
forming a fourth barrier layer above the second channel region;
forming a source region; and
forming a drain region.

16. The method of claim 15, further comprising forming a buffer layer above the substrate, wherein a portion of the buffer layer is below the source region, and wherein another portion of the buffer layer is below the drain region.

17. The method of claim 15, further comprising forming a third gate layer above the fourth barrier layer, wherein:
the first barrier layer and the second barrier layer extend between a region adjacent to or below the drain region and a region adjacent to or below the source region; and
the third barrier layer and the fourth barrier layer extend between the region adjacent to or below the drain region and the region adjacent to or below the source region.

18. The method of claim 15, wherein a portion of the source region is adjacent to a portion of each of the first barrier layer, the second barrier layer, and the first channel region.

19. The method of claim 15, wherein:
forming the source region comprises:
forming a doped semiconductor region; and
forming a source contact above the doped semiconductor region, the doped semiconductor region having a portion adjacent to a portion of each of the first barrier layer, the second barrier layer, and the first channel region; and
forming the drain region comprises:
forming another doped semiconductor region; and
forming a drain contact above the other doped semiconductor region, the other doped semiconductor region having a portion adjacent to another portion of each of the first barrier layer, the second barrier layer, and the first channel region.

20. The method of claim 15, wherein forming the source region comprises forming a first portion of the source region and a second portion of the source region such that each of the first barrier layer, the second barrier layer, and the first channel region is disposed between the first portion of the source region and the second portion of the source region.
